(19) United States
(12) Patent Application Publication
(10) Pub. No.: US 2005/0014317 A1
(43) Pub. Date: Jan. 20, 2005

(54) Method for forming inductor in semiconductor device

(76) Inventor: Sung Gyu Pyo, Yongin-Shi (KR)

Correspondence Address: JACOBSON HOLMAN PLLC, 400 SEVENTH STREET N.W., SUITE 600, WASHINGTON, DC, 20004, US

(21) Appl. No.: 10/731,478

(22) Filed: Dec. 10, 2003

(30) Foreign Application Priority Data
Jul. 18, 2003 (KR) 2003-49462
Jul. 18, 2003 (KR) 2003-49463

(51) Int. Cl. H01L 21/338

(52) U.S. Cl. 438/184

(57) ABSTRACT

The present invention relates to a method of forming a 3-D inductor using RF-MEMS. According to the present invention, an inductor may be formed by depositing copper by means of a spin-on force fill method using a solution containing nano-scale copper particles or copper precursors without depositing an anti-diffusion film or a seed layer, performing a baking process, and then burying copper by means of a spin-on force fill method including performing an annealing process. A 3-D inductor may be formed by forming a given first metal layer pattern, plating a copper layer to form an air gap bridge, forming a second metal layer pattern on the air gap bridge, plating a copper layer to form an inductor, and then removing the first and second metal layer patterns.

### BACKGROUND

1. Field of the Invention

The present invention relates to a method of forming an inductor in a semiconductor device and, more specifically to a method of forming an inductor by burying copper by means of a spin-on force fill method using a solution containing nano-scale copper particles or copper precursors, or a 3-D inductor by forming a given first metal layer pattern, plating a copper layer to form an air gap bridge, forming a given second metal layer pattern on the air gap bridge, plating a copper layer to form an inductor, and then removing the first and second metal layer patterns.

2. Discussion of Related Art

As competition in technology is increasingly accelerated worldwide and cooperation among countries is strengthened, it is well known that a country's technology results in competitiveness that is at the center of a business among countries. It is a trend that advanced countries are further accelerating development of technology through changes in paradigm in order to stand in a unique position in terms of technology competitiveness. As if semiconductor has brought about the revolution of the twentieth century, micro electromechanical system (hereinafter, referred to as “MEMS”) technology will surface as technology that will cause revolution in information communications and bio/medicine fields in the twenty-first century. MEMS is also referred to as a micro system, a micro machine, micro mechatronics, etc. MEMS refers to a subminiature system or subminiature precision machinery and is defined as a term to commonly designate small electrical/mechanical devices. In a region where the MEMS device operates, a new concept or principle contrary to an existing common sense, where a design rule or operating principle operated in an existing micro world, is possible.

As noted above, in the twentieth century, revolution in technology only and advancements in independent fields are made. In the twenty-first century, however, a native region of technology in each industry field is destructed and assistance with other fields is inevitable. In other words, different technologies are fused to create a new technology. Furthermore, humanistic technology development considering humans and environments not development of only technology is required. This need may be satisfied by human-friendly technology in which electronic/electric fields (semiconductor, display fields), a machinery field, a miniature field and a bio field, all of which properties of the MEMS technology, are adequately combined. As such, MEMS has a control and instrumentation engineering, a biomedical engineering, an aerospace engineering, a precision engineering, a biotechnology, mechanical design engineering, a materials science & engineering put together. In addition, MEMS referred to a system having mechanical properties and electrical/electronic properties in the past but a system having optical/chemical/hydraulic/biological properties in recent years. Also, MEMS realized based on semiconductor and display process has a size of less than mm to less than nm. A micro machining requires mechanical factors attaching greater importance to a micro unit, and technology of manufacturing a subminiature machine apparatus requires a space in which an object within the machine apparatus can move or vibrate as well as micro electronic device manufacture technology. A trend for implementing a 3-D space is further important. The machining method includes bulk micro machining, a surface micro machining lithographic galvanotoming, adtorming (LIGA) (photographs, printing, electroplating, molding) for structural variety and the 3-D structure, and the like. MEMS technology is composite technology. The advent of the system-on-chip (SoC) allows setting application necessary for clients not forming a market with manufactured products and implementing systems suitable for the applications so that technology of constitutional elements thereof are composite. Therefore, it is possible to mix various technologies and to rapidly cope with market situation in the future in which a life cycle is gradually shortened. Such technology development necessarily requires the intellectual property (IP) rights and an IP pervasive effect is significantly increased. In case of U.S.A., IBM has the highest number of patent applications. The University of California and Texas Instrument Inc. are the second highest below IBM. 70% or more of a main patent is originated from U.S.A., Japan and Germany.

MEMS technology is technology originated from integration of various technologies. As IP is a prerequisite industry, nation-wide development and encouragement are indispensable. Ministry of Economy, Trade and Industry of Japan started an industry science technology frontier program by investing ¥25 billion during 10 years beginning 1991. National Science Foundation (NSF) in U.S.A. has consistently performed MEMS development 10 years ago. In Europe, a joint investment of European community is planned and expenditures from $50 million to $200 million are invented for MEMS technology development. Of various MEMS fields, a RF-MEMS 3-D inductor formation technology is highlighted since it will be first commercialized in semiconductor device applications using the MEMS technology.

As a paradigm in the information communication field is changed, there is an increasing need for a communication scheme that is not limited to time and location. The field of the wireless mobile communication is one that is mostly suitable for this need and has been rapidly developed. Due to wireless communications being advanced, more radio frequency resources are needed. In line with it, the need for materials, elements and circuits operating in the radio frequency increases. As the materials, elements and circuits are used in a region having a high frequency, they are classified as radio frequency (RF) components and IC.

A complementary metal-oxide semiconductor (hereinafter, referred to as “CMOS”) is one using a silicon material. As MEMS is advanced, the CMOS has a good frequency property. The CMOS allows a low-priced chip to be fabricated using well-developed process technology intact since it uses silicon. The SoC surfaces as technology that is mostly suitable for a single chip since an intermediate frequency band of a system, i.e., up to a digital element can be integrated. A Bi (bipolar)-CMOS is one in which bipolar elements and CMOS elements are implemented on a silicon substrate at the same time. If SiGe instead of silicon is used as the bipolar element, only advantages of the bipolar and CMO devices can be obtained. High function and low price can be contrived by adding SiGe technology to well-established silicon semiconductor technology.

An indispensable element for implementing the silicon CMOS technology in the RF IC is an inductor. It is, however, impossible to obtain Q (quality factor) required in the RF IC only using a standard logic process. In order to obtain a high Q, it is required that an amount of parasitic resistance generating in a metal wiring, and loss of eddy current and displacement current into the silicon substrate be reduced. Meanwhile, it is possible to lower resistance by increasing the thickness of a metal used as an inductor higher than the thickness applied in the standard process. The quality factor can be increased using a low-resistance metal such as copper. Furthermore, it is advantageous that it is a circular shape in structure than the square shape, the distance between the metal wirings is narrow and the center of the inductor is empty. It is known to be adequate that the empty diameter of the inductor is about ⅓ of a total diameter of the inductor. If the thickness of a metal for forming the inductor, however, an increase in parasitic capacitance due to the increased thickness is reduced but parasitic resistance component is significantly reduced. There is no change in inductance depending on the thickness of the metal. Furthermore, as the number of a turn in an inductor is increased, inductance is increased but the quality factor is reduced at a given number of a turn (usually 5.5). In other words, the quality factor is reduced since parasitic resistance and parasitic capacitance are increase rather than the amount of increase in inductance depending on an increase in the number of a turn. Furthermore, in a CMOS process of 5 or more layers, metal layers are stacked to reduce resistance of the inductor, thus increasing the quality factor. If this technology is used, most inductance (less than 10 nH) used in the RF circuit can be implemented to have that of a band pad. In this case, however, there is a shortcoming that the resonant frequency is lowered due to increased capacitance between the metal layers.

Another method for increasing the quality factor of the inductor is to reduce parasitic component with the silicon substrate. A main reason of decreasing the quality factor is displacement current flowing into the silicon substrate through a parasitic capacitor located between eddy current induced to the substrate as a magnetic field of the inductor is varied, the inductor and the substrate. A GaAs substrate used in a compound semiconductor is a semi-insulating substrate whose resistivity is high. It is thus rarely problematic with respect to parasitic component with the substrate but is a big problem in the silicon substrate. A condition where digital circuits and RF circuits are difficult to coexist in the same chip due to transfer of a signal through the silicon substrate, may take place. Options for reducing the effect with the silicon substrate may include a method using a silicon substrate of a high resistance or a substrate of a silicon-on-insulator (hereinafter, referred to as “SOI”) structure or a method using a guard ring. It is reported that a SOI wafer is very effective at low frequency but is rarely effective at high frequency of over 1 GHz. This is because the thickness of a burial oxide film is usually 2000 to 5000 Å in the SOI wafer but is lower than the thickness of a necessary oxide film in order to isolate up to a high frequency band. Though the guide ring using a dip N-well is influential, it does not meet the requirements of a system level. Furthermore, a method of making bigger the distance of the inductor from the silicon substrate using an upper metal layer in order to reduce parasitic capacitance, a method of forming a N-well below the field oxide film and then applying a reverse bias to the well by forming the inductor on a field oxide film, may be used. Also, there is a method of forming a ground layer under the inductor to preclude coupling with the substrate. What the ground layer is patterned into several pieces in order to reduce reduction in inductance due to the ground layer is called a patterned ground shield (PGS). The shortcoming of the inductor using the PGS is that the resonant frequency and the quality factor are reduced due to an increase in components of parasitic capacitance with the ground layer.

Guidelines that can be considered in designing the inductor, are as follows:

First, it is required that the space between the metal wirings be minimized. By doing so, space of the inductor is minimized and mutual inductance is maximized, thus increasing the quality factor.

Second, it is required that the inductor must be implemented in an upper metal layer. The reason is that parasitic capacitance into the substrate can be minimized.

Third, the metal wiring must be formed as thick as possible. In other words, low serial resistors have to be secured. If the width is too big, an area of the inductor is increased. As this may increase parasitic capacitance and damages to the substrate, an adequate condition must be induced.

Fourth, a hollow inductor must be implemented. As an eddy current effect (negative mutual coupling) can be reduced through the hollow inductor, the inner diameter must be larger five times than the width of a metal.

Fifth, the higher the number of a turn, the greater the area of the inductor and the higher the resistance effect. As this causes parasitic capacitance to increase, thus lowering the quality factor, an adequate condition for the number of the turn has to be induced.

In these requirements, due to a decoupling problem, research in which a trench is inserted below the inductor and the thickness of an insulating layer is increased or a ground plate is inserted, has been made.

The above description is focused on general facts on the inductor. A method of forming the inductor, currently applied to a copper wiring, will now be described with reference to FIGS. 1A to 1C.

FIGS. 1A to 1C are cross-sectional views shown to explain a method of forming an inductor in a semiconductor device according to a prior art.

Referring to FIG. 1A, an interlayer insulating film 12 is formed on a semiconductor substrate 11 in which given components are formed. A given region of the interlayer insulating film 12 is etched to form a trench through which a given region of the semiconductor substrate 11 is exposed.

By reference to FIG. 1B, an anti-diffusion film 13 and a seed layer 14 are formed on the entire structure. A copper layer 15 is then formed by means of an electroplating method so that the trench is buried. In this case, the electroplating method may be performed using a chemical catalyst.

Referring to FIG. 1C, the copper layer 15, the seed layer 14 and the anti-diffusion film 13 are treated by a chemical mechanical polishing (CMP) process, thus forming an inductor.

In case where the inductor is formed through the above process, the following problems take place.

First, an interlayer insulating film is formed over 2 to 3 μm. Etching the insulating film thickly formed as such is very difficult actually. Furthermore, as an etch time per one wafer sheet is very long, it increases the cost price.

Second, if an electroplating process that is currently applied to a copper wiring process is used, the cost price in process is remarkably increased. There is a high possibility that a seam or void may occur at the center of the inductor due to conformal filling. This degrades the stability in process. Furthermore, it is a prerequisite that a large amount of an additive be avoided.

Third, what the copper plating film of over 3 to 5 μm is treated by the CMP is a further big problem. In other words, as time taken to polish a copper film having a very large step and thickness is too long, it greatly affects the yield and cost price, thus significantly increasing the device price.

### SUMMARY OF THE INVENTION

The present invention is directed to a method of forming an inductor in a semiconductor device, which can develop a RF-CMOS device through the fusion of nano technology and MEMS technology, in such a way that the inductor is formed by burying copper by means of a spin-on force fill method using a solution containing nano-scale copper particles or copper precursors, thus reducing the number of a process and removing any possibility of defects that may occur upon electroplating.

According to the present invention, there is provided a method of forming an inductor in a semiconductor device, which can overcome difficulty in an etching in the process of forming the inductor using a damascene process and difficulty in a CMP process due to a large step height, in such a manner that after a given first metal layer pattern is formed, an air gap bridge is formed using a copper layer by means of a plating process, a given second metal layer pattern is formed on the air gap bridge, an inductor is formed using a copper layer by means of a plating process, and the first and second metal layer patterns are then moved to form a 3-D inductor using RE-MEMS.

According to a first embodiment of the present invention, there is provided a method for forming an inductor in a semiconductor device, comprising the steps of forming a first photoresist film on a semiconductor substrate in which a given structure is formed, and then patterning the first photoresist film so that a given region of the semiconductor substrate is exposed; depositing copper by means of a spin-on method using a solution containing nano-scale copper particles, performing a baking process, and then performing an annealing process to form a first copper layer in the patterned first photoresist film; forming a second photoresist film on the entire structure, and then patterning the second photoresist film to expose given portions of the first photoresist film and the first copper layer; depositing copper by means of the spin-on method using the solution containing the nano-scale copper particles, performing a baking process, and then performing an annealing process to form a second copper layer between the patterned second photoresist films; and removing the first and second photoresist films.

According to a second embodiment of the present invention, there is provided a method for forming an inductor in a semiconductor device, comprising the steps of forming a first photoresist film on a semiconductor substrate in which a given structure is formed, and then patterning the first photoresist film so that a given region of the semiconductor substrate is exposed; depositing copper by means of a spin-on method using copper precursors, performing a baking process, and then performing an annealing process to form a first copper layer in the patterned first photoresist film; forming a second photoresist film on the entire structure, and then patterning the second photoresist film to expose given portions of the first photoresist film and the first copper layer; depositing copper by means of the spin-on method using the copper precursors, performing a baking process, and then performing an annealing process to form a second copper layer between the patterned second photoresist films; and removing the first and second photoresist films.

According to a third embodiment of the present invention, there is provided a method of forming an inductor in a semiconductor device, comprising the steps of forming a first photoresist film on a semiconductor substrate in which a given structure is formed, and then patterning the first photoresist film so that a given region of the semiconductor substrate is exposed; depositing aluminum by means of a spin-on method using nano-scale aluminum particles or aluminum precursors, performing a baking process, and then performing an annealing process to form a first aluminum layer in the patterned first photoresist film; forming a second photoresist film on the entire structure, and then patterning the second photoresist film to expose give portions of the first photoresist film and the first aluminum layer; depositing aluminum by means of the spin-on method using the nano-scale aluminum particles or the aluminum precursors, performing a baking process, and then performing an annealing process to form a second aluminum layer between the patterned second photoresist films; and removing the first and second photoresist films.

According to a second embodiment of the present invention, there is provided a method of forming an inductor in a semiconductor device, comprising the steps of forming a first metal layer on a semiconductor substrate in which a given structure is formed, and then patterning the first metal layer so that a given region of the semiconductor substrate is exposed; forming a first copper layer on the entire structure and then polishing the first copper layer; forming a second metal layer on the entire structure, and then patterning the second metal layer to expose given regions of the first metal layer and the first copper layer; forming a second copper layer on the entire structure and then polishing the second copper layer; and removing the first and second metal layers.

According to a fifth embodiment of the present invention, there is provided a method of forming an inductor in a semiconductor device, comprising the steps of forming a first metal layer on a semiconductor substrate in which a given structure is formed, and then patterning the first metal layer so that a given region of the semiconductor substrate is exposed; forming a first aluminum layer on the entire structure and then polishing the first aluminum layer; forming a second metal layer on the entire structure, and then patterning the second metal layer to expose given regions of the first metal layer and the first aluminum layer; forming a second aluminum layer on the entire structure and then polishing the second aluminum layer; and removing the first and second metal layers.

### BRIEF DESCRIPTION OF THE DRAWINGS

FIGS. 1A to 1C are cross-sectional views shown to explain a method of forming an inductor in a semiconductor device according to a prior art;

FIGS. 2A to 2E are cross-sectional views shown to explain a method of forming an inductor in a semiconductor device according to one embodiment of the present invention; and

FIGS. 3A to 3E are cross-sectional views shown to explain a method of forming an inductor in a semiconductor device according to another embodiment of the present invention.

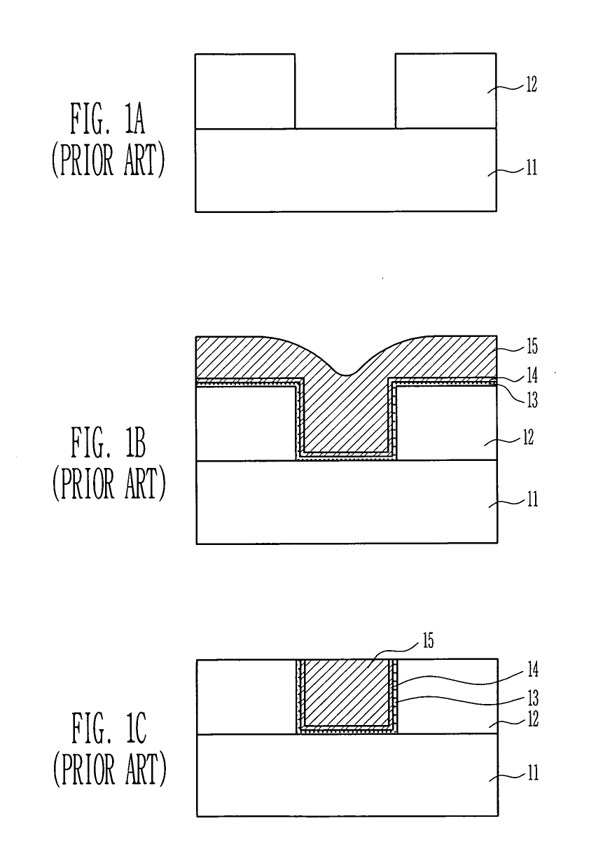

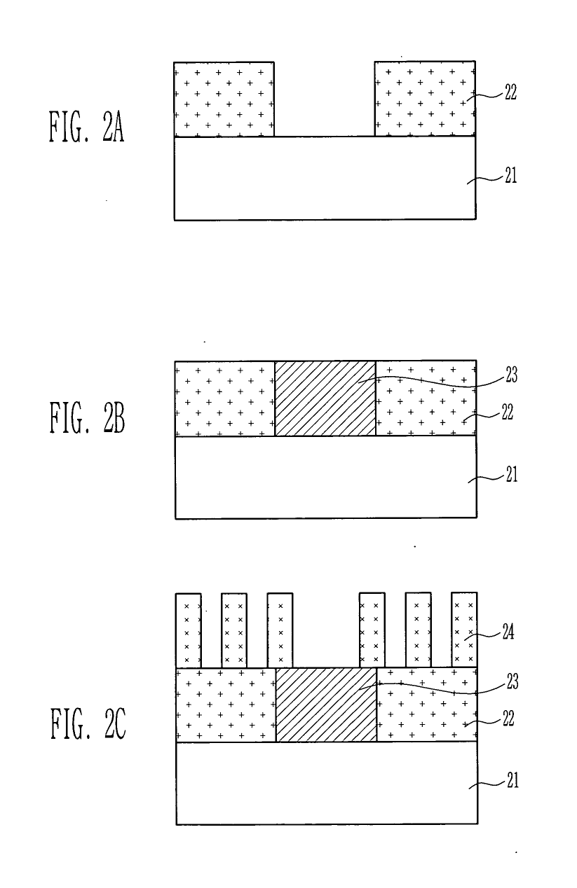

### DETAILED DESCRIPTION OF PREFERRED EMBODIMENTS

Now the preferred embodiments according to the present invention will be described with reference to the accompanying drawings. Since preferred embodiments are provided for the purpose that the ordinary skilled in the art are able to understand the present invention, they may be modified in various manners and the scope of the present invention is not limited by the preferred embodiments described later.

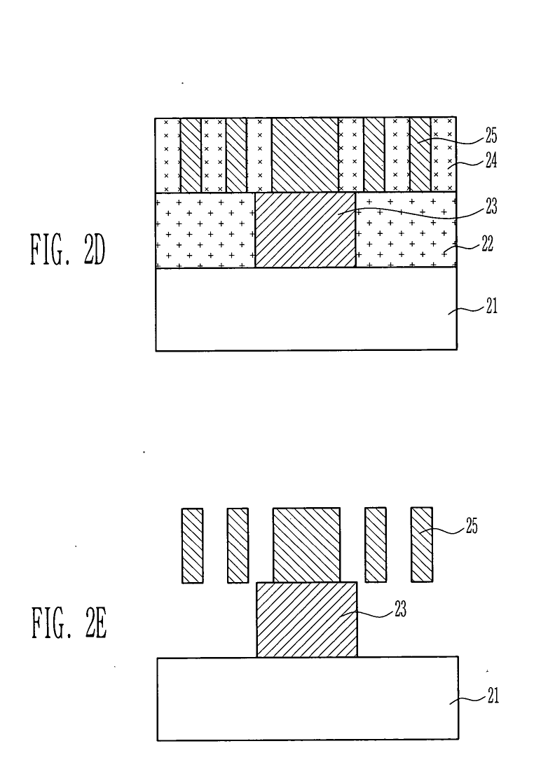

FIGS. 2A to 2E are cross-sectional views shown to explain a method of forming a 3-D inductor using MEMS according to one embodiment of the present invention.

Referring to FIG. 2A, a first photoresist film 22 is formed on a semiconductor substrate 21 in which a given device, for example, a CMOS device is formed. In this case, the first photoresist film 22 is formed to have a height corresponding to the distance between an underlying device and an inductor that will be formed on an upper side. As the distance between the underlying device and the inductor is in range of 100 Å to 500 μm, the first photoresist film 22 is formed to have a thickness corresponding to that distance. Furthermore, photolithography and developing processes are performed to pattern the first photoresist film 22 so that a given region of the semiconductor substrate 21 is exposed.

By reference to FIG. 2B, a first copper layer 23 is formed between the first photoresist films 22 that are patterned by means of a spin-on force fill method using a solution containing nano-scale copper particle or a copper precursor. In this case, the spin-on force fill method is a method of depositing copper using a spin-on method, performing a baking process, and performing an annealing process under hydrogen atmosphere to force-fill and reflow copper, thus forming the first copper layer 23. By doing so, an air gap bridge is formed between the device and the inductor.

In the above, the nano-scale copper particles are 1 to 20 nm in size. Further, the solution containing the nano-scale copper particles or the copper precursors are deposited at the rate of 100 to 5000 rpm under a temperature condition of −10 to 100° C. They are deposited at a high rate of about 5000 rpm in an initial stage of deposition during 1 to 10 sec.

The baking process is performed under a temperature condition of 200 to 500° C. under hydrogen atmosphere and may be implemented in a single or a multi-stage step. The baking process of the single step is a method of performing the baking at any one temperature of 200 to 500° C. for 1 second to 10 minutes. The baking process of the multi-stage step is a method of performing the baking at several temperatures of 200 to 500° C. for 1 second to 10 minutes. Meanwhile, the hydrogen atmosphere upon the baking process includes using a case of employing hydrogen only and a case of employing a hydrogen-contained gas such as hydrogen and argon (0 to 95%), hydrogen and nitrogen (0 to 95%), and the like.

After the baking process is performed, while an annealing process is consecutively performed at a temperature of 200 to 500° C. under a hydrogen atmosphere for 1 second to 10 minutes, a force fill is performed at a pressure of 0.1 to 100 Mpa, thus forming a dense copper layer. At this time, the force fill method may use a single step, a multi-stage step or a sin curve type pressure and repeated once to 10 times. When pressure is applied using the single step and the multi-stage step, a single gas and a mixed gas can be used. In case of using the multi-stage steps, a single hydrogen gas is used or a mixed gas of hydrogen, argon, helium, etc. is used. A process of using a hydrogen gas is then repeated 1 to 10 times.

With reference to FIG. 2C, a second photoresist film 24 is formed on the entire structure. The second photoresist film 24 is patterned so that given portions of the underlying first photoresist film 22 and the first copper layer 23 depending on the number of a turn of a desired inductor.

By reference to FIG. 2D, second copper layers 25 are formed between the second photoresist films 24 that are patterned by a spin-on force fill method using a solution containing nano-scale copper particles or copper precursors. At this time, the spin-on force fill method is performed in the same process as that describe above.

Referring to FIG. 2E, the first and second photoresist films 22 and 24 formed in the air bridge and the inductor are moved to form an inductor of a RF-MEMS 3-D structure. At this time, before the first and second photoresist films 22 and 24 are removed, an annealing process is performed. The annealing process is performed at a temperature of 50 to 500° C. for 1 minute to 5 hours and under a hydrogen, argon, nitrogen or forming gas atmosphere.

In the above, although copper is used in order to form the bridge or the inductor, aluminum may be used instead. Further, in the present embodiment, the method of forming the 3-D inductor using RF-MEMS has been described. The method, however, can be applied to RF-CMOS devices to which other inductor structures other than 3-D are applied. The method of forming the air bridge in the 3-D inductor structure is applied to implement an inductor of a RF-CMOS device.

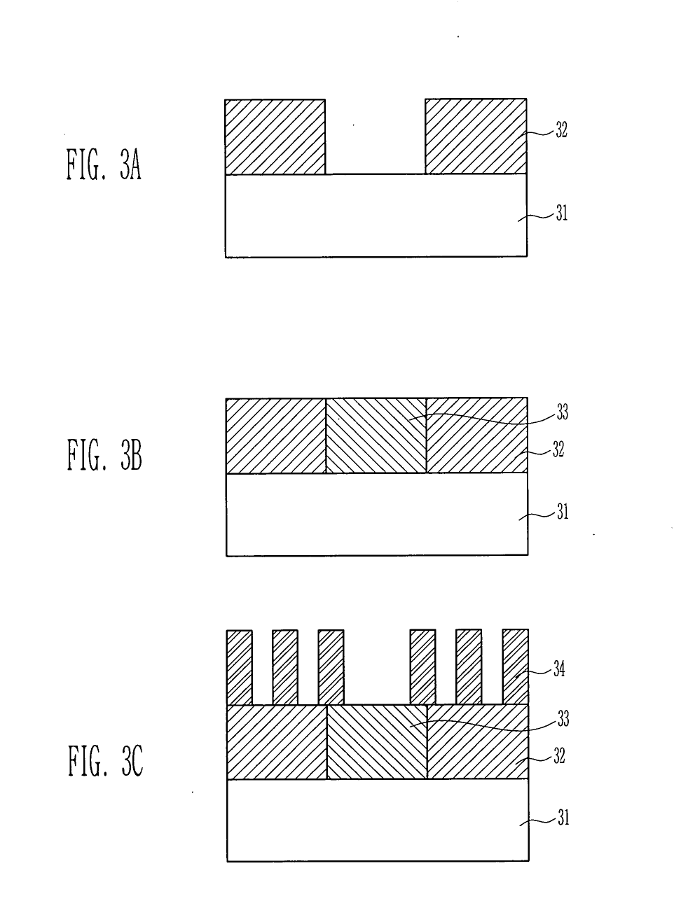

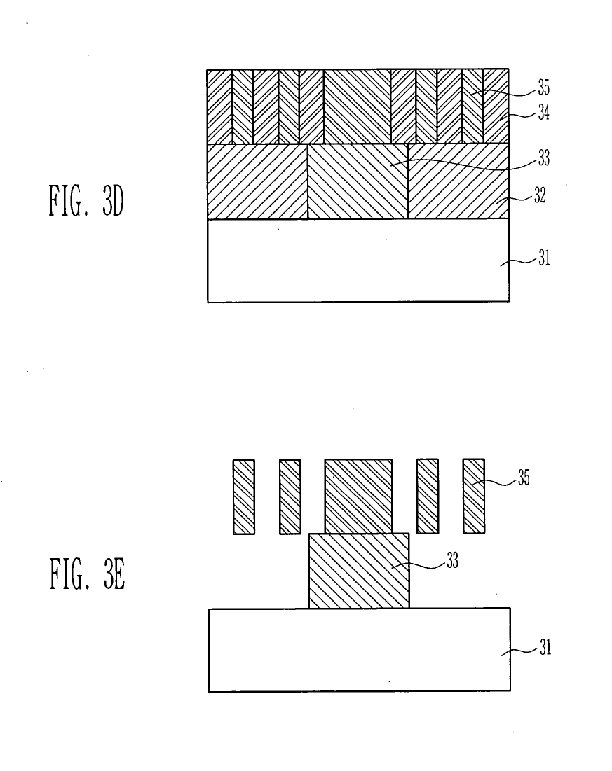

FIGS. 3A to 3E are cross-sectional views shown to explain a method of forming a 3-D inductor using RF-MEMS according to another embodiment of the present invention.

Referring to FIG. 3A, a first metal layer 32 is formed on a semiconductor substrate 31 in which a given structure, for example, a CMOS device is formed. The first metal layer 32 is then patterned so that a given region of the semiconductor substrate 31 is exposed. In this case, the first metal layer 32 may be formed using all kinds of metals that represent a selective etch property with a copper layer to be formed later and in which copper can be used in a plating process, for example, nickel (Ni), cobalt (Co), titanium (Ti), aluminum (Al), tungsten (W) and tantalum (Ta). Meanwhile, the first metal layer 32 is formed by a deposition or plating method and is formed in thickness corresponding to the distance between the CMOS device and the inductor, for example, in thickness of 100 Å to 500 μm.

By reference to FIG. 3B, a first copper layer 33 is formed on the entire structure by means of an electroplating method or an electroless plating method. The first copper layer 33 is then polished by means of a CMP process. An air gap bridge is formed between the CMOS device and the inductor. At this time, the plating process for forming the first copper layer 33 is performed using a plating solution containing not any additive of polymer components such as a suppressor, an accelerator, a leveler, etc. Furthermore, the electroplating method is performed using a plating solution in which an additive is not added to a solution, in which H₂SO₄ and CuSO₄ are mixed in the ratio of 1:99 to 99:1. Meanwhile, HCl is also used. The concentration of HCl keeps 1 to 1000 ppm. Also, the electroplating method using a plating solution to which an additive is not added may employ forward DC plating, pulse-reverse plating, pulse plating, and the like. A multi-stage step in which these methods are mixed can be also used. In addition, in case where the first copper layer 33 is formed using the electroless plating method, a process of adding a surface cleaning or activation agent may be added.

With reference to FIG. 3C, a second metal layer 34 is formed on the entire structure. In this case, the second metal layer 34 is formed considering the thickness of the inductor. Like in the first metal layer 32, the second metal layer 34 may be formed using all kinds of metals that represent a selective etch property with the copper layer and in which copper can be used in a plating process, for example, nickel (Ni), cobalt (Co), titanium (Ti), aluminum (Al), tungsten (W) and tantalum (Ta). Depending on the number of a turn of a desired inductor, a second metal layer 34 is patterned so that portions of the underlying first metal layer 32 and the first copper layer 33 are exposed.

Referring to FIG. 3D, a second copper layer 35 is formed on the entire structure by means of an electroplating method or an electroless plating method. The second copper layer 35 is then polished. The second copper layer 35 is formed by means of the same method as that of forming the first copper layer 33.

By reference to FIG. 3E, the first and second metal layers 32 and 34 are removed to form an inductor of a RF-MEMS 3-D structure. At this time, before the first and second metal layers 32 and 34 are removed, an annealing process is performed. The annealing process is performed at a temperature of 50 to 500° C. for 1 minute to 5 hours and under a hydrogen, argon, nitrogen or forming gas atmosphere.

In the above, although copper is used in order to form the bridge or the inductor, aluminum may be used instead. Further, in the present embodiment, the method of forming the 3-D inductor using RF-MEMS has been described. The method, however, can be applied to RF-CMOS devices to which other inductor structures other than 3-D are applied. The method of forming the air bridge in the 3-D inductor structure is applied to implement an inductor of a RF-CMOS device.

According to the present invention described above, an inductor is formed by burying copper by means of a spin-on force fill method using nano copper particles or copper precursors. Thus there is no need for a process of forming an anti-diffusion film and a seed layer that is required to bury copper by means of an electroplating method. Accordingly, the number of a process can be significantly reduced and a copper wiring burial process can be performed with simple equipments and a low cost. Furthermore, it is possible to overcome difficulty in an etching and difficulty in a CMP process due to a high step. Also, the cost for forming an inductor can be greatly reduced by shortening a CMP process time. A 3-D inductor can be easily implemented by simplifying the level of process integration. It is thus possible to develop a high-performance device having a high degree of reliability required in communication devices, etc.

Furthermore, after forming a given a first metal layer pattern, an air gap bridge is formed using a copper layer by means of a plating process, a given second metal layer pattern is formed on the air gap bridge, an inductor is formed using a copper layer by means of a plating process, and the first and second metal layer patterns are then moved to form a 3-D inductor using RE-MEMS. It is therefore possible to simplify the process without the need for a process of forming an anti-diffusion film and a seed layer, overcome difficulty in an etching in the process of forming an inductor using a damascene process and difficulty in a CMP process due to a large step, and further enhance properties of a copper active device using a plating solution in which an additive is not added.

Although the foregoing description has been made with reference to the preferred embodiments, it is to be understood that changes and modifications of the present invention may be made by the ordinary skilled in the art without departing from the spirit and scope of the present invention and appended claims.

1. A method for forming an inductor in a semiconductor device, comprising the steps of:
forming a first photoresist film on a semiconductor substrate in which a given structure is formed, and then patterning the first photoresist film so that a given region of the semiconductor substrate is exposed;
depositing copper by means of a spin-on method using a solution containing nano-scale copper particles, performing a baking process, and then performing an annealing process to form a first copper layer in the patterned first photoresist film;
forming a second photoresist film on the entire structure, and then patterning the second photoresist film to expose given portions of the first photoresist film and the first copper layer;
depositing copper by means of the spin-on method using the solution containing the nano-scale copper particles, performing a baking process, and then performing an annealing process to form a second copper layer between the patterned second photoresist films; and
removing the first and second photoresist films.

2. The method as claimed in claim 1, wherein the nano-scale copper particles are formed with a size in the range of 1 nm to 20 nm.

3. The method as claimed in claim 1, wherein the solution containing the nano-scale copper particles is deposited at a temperature in the range of −10° C. to 100° C. with a rate in the range of 100 rpm to 5000 rpm.

4. The method as claimed in claim 1, wherein the baking process is performed in a single step or a multi-stage step at a temperature in the range of 200° C. to 500° C. under a hydrogen atmosphere.

5. The method as claimed in claim 4, wherein the baking process of the single step includes performing a baking process at any one temperature in the range of 200° C. to 500° C. for 1 second to 10 minutes.

6. The method as claimed in claim 4, wherein the baking process of the multi-stage step includes performing a baking process at several temperatures in the range of 200° C. to 500° C. for 1 second to 10 minutes.

7. The method as claimed in claim 4, wherein in case where the hydrogen atmosphere upon the baking process contains hydrogen only, a hydrogen-mixed gas such as hydrogen and argon (0 to 95%), hydrogen and nitrogen (0 to 95%), etc. is used.

8. The method as claimed in claim 1, wherein the annealing process is performed at a temperature in the range of 200° C. to 500° C. under a hydrogen atmosphere for 1 second to 10 minutes, while a pressure of 0.1 to 100 Mpa is applied.

9. The method as claimed in claim 8, wherein the pressure is repeatedly applied once to ten times in a single step, a multi-stage step or a sin curve type.

10. The method as claimed in claim 9, wherein if the pressure is applied using the single step and the multi-stage step, a single gas and a mixed gas are used.

11. The method as claimed in claim 9, wherein if the pressure is applied using the multi-stage step, a process of using a single hydrogen gas or a mixed gas such as hydrogen, argon, helium, etc. and finally using a hydrogen gas, is repeated once to ten times.

12. The method as claimed in claim 1, further comprising performing an annealing process before the first and second photoresist films are removed.

13. The method as claimed in claim 12, wherein the annealing process is performed at a temperature in the range of 50° C. to 500° C. for 1 minute to 5 hours and under a hydrogen, argon, nitrogen or forming gas atmosphere.

14. A method for forming an inductor in a semiconductor device, comprising the steps of:
forming a first photoresist film on a semiconductor substrate in which a given structure is formed, and then patterning the first photoresist film so that a given region of the semiconductor substrate is exposed;
depositing copper by means of a spin-on method using copper precursors, performing a baking process, and then performing an annealing process to form a first copper layer in the patterned first photoresist film;
forming a second photoresist film on the entire structure, and then patterning the second photoresist film to expose given portions of the first photoresist film and the first copper layer;
depositing copper by means of the spin-on method using the copper precursors, performing a baking process, and then performing an annealing process to form a second copper layer between the patterned second photoresist films; and
removing the first and second photoresist films.

15. A method for forming an inductor in a semiconductor device, comprising the steps of:
forming a first photoresist film on a semiconductor substrate in which a given structure is formed, and then patterning the first photoresist film so that a given region of the semiconductor substrate is exposed;
depositing aluminum by means of a spin-on method using nano-scale aluminum particles or aluminum precursors, performing a baking process, and then performing an annealing process to form a first aluminum layer in the patterned first photoresist film;
forming a second photoresist film on the entire structure, and then patterning the second photoresist film to expose given portions of the first photoresist film and the first aluminum layer;
depositing aluminum by means of the spin-on method using the nano-scale aluminum particles or the aluminum precursors, performing a baking process, and then performing an annealing process to form a second aluminum layer between the patterned second photoresist films; and
removing the first and second photoresist films.

16. A method for forming an inductor in a semiconductor device, comprising the steps of:
forming a first metal layer on a semiconductor substrate in which a given structure is formed, and then patterning the first metal layer so that a given region of the semiconductor substrate is exposed;
forming a first copper layer on the entire structure and then polishing the first copper layer;
forming a second metal layer on the entire structure, and then patterning the second metal layer to expose given regions of the first metal layer and the first copper layer;
forming a second copper layer on the entire structure and then polishing the second copper layer; and
removing the first and second metal layers.

17. The method as claimed in claim 16, wherein the first and second metal layers are formed using one of nickel (Ni), cobalt (Co), titanium (Ti), aluminum (Al), tungsten (W) and tantalum (Ta).

18. The method as claimed in claim 16, wherein first and second copper layers are formed using an electroplating method or an electroless plating method.

19. The method as claimed in claim 18, wherein the electroplating method is performed using a plating solution in which an additive is not added to a solution, in which H₂SO₄ and CuSO₄ are mixed in the ratio of 1:99 to 99:1.

20. The method as claimed in claim 19, wherein the electroplating method using the plating solution to which the additive is not added is performed using a forward DC plating method, a pulse-reverse plating method, or a pulse plating method, or a multi-stage plating step in which these methods are mixed.

21. The method as claimed in claim 18, wherein the electroplating method is performed while maintaining a concentration of HCl in the range of 1 to 1000 ppm.

22. The method as claimed in claim 18, wherein the electroless plating method further includes performing a process of adding a surface cleaning and activation agent.

23. The method as claimed in claim 16, wherein the first and second copper layers are formed by means of a plating process using a plating solution containing not any additive of polymer components such as a suppressor, an accelerator, a leveler, etc.

24. The method as claimed in claim 16, further comprising the step of performing an annealing process before the first and second metal layers are removed.

25. The method as claimed in claim 24, wherein the annealing process is performed at a temperature in the range of 50° C. to 500° C. for 1 minute to 5 hours under a hydrogen, argon, nitrogen or forming gas atmosphere.

26. A method for forming an inductor in a semiconductor device, comprising the steps of:
forming a first metal layer on a semiconductor substrate in which a given structure is formed, and then patterning the first metal layer so that a given region of the semiconductor substrate is exposed;
forming a first aluminum layer on the entire structure and then polishing the first aluminum layer;
forming a second metal layer on the entire structure, and then patterning the second metal layer to expose given regions of the first metal layer and the first aluminum layer;
forming a second aluminum layer on the entire structure and then polishing the second aluminum layer; and
removing the first and second metal layers.
